(19) United States
(12) Patent Application Publication
(10) Pub. No.: US 2007/0187746 A1
(43) Pub. Date: Aug. 16, 2007

(54) NONVOLATILE SEMICONDUCTOR MEMORY DEVICE WITH TRENCH STRUCTURE

(75) Inventor: Masahiko KASHIMURA, Kanagawa (JP)

Correspondence Address: SUGHRUE MION, PLLC, 2100 PENNSYLVANIA AVENUE, N.W., SUITE 800, WASHINGTON, DC, 20037, US

(73) Assignee: NEC ELECTRONICS CORPORATION, Kanagawa (JP)

(21) Appl. No.: 11/675,428

(22) Filed: Feb. 15, 2007

(30) Foreign Application Priority Data
Feb. 16, 2006 (JP) 2006-039778

(51) Int. Cl. H01L 29/788

(52) U.S. Cl. 257/315

(57) ABSTRACT

In a nonvolatile semiconductor memory device, a semiconductor substrate has trenches formed to extend in parallel. A first electrode formed on the semiconductor substrate through an insulating film in each of the trenches, and a second electrode is formed on the first electrodes and the semiconductor substrate through the insulating film. A diffusion layer is formed in a predetermined depth of the semiconductor substrate in association with each of the trenches, and a trap film as a part of the insulating film configured to trap electric charge. A channel region is formed between adjacent two of the diffusion layers without any diffusion layer.

### BACKGROUND OF THE INVENTION

1. Field of the Invention

The present invention pertains to a nonvolatile semiconductor memory device. In particular, the present invention is directed to a nonvolatile semiconductor memory device that write/erasure of data is possible electrically, and to a method for manufacturing the nonvolatile semiconductor memory device.

2. Description of the Related Art

The Metal Oxide Nitride Oxide Silicon (MONOS) transistor is known as a memory cell transistor used for a nonvolatile semiconductor memory device. The MONOS transistor is a kind of Metal Insulator Silicon (MIS) transistor, and an Oxide Nitride Oxide (ONO) film in which a silicon oxide film, a silicon nitride film and a silicon oxide film are sequentially laminated is used as a gate insulating film. The silicon nitride film in the ONO film has a property to trap electric charge. For example, it is possible for the silicon nitride film to trap the electrons by applying suitable voltages to a gate electrode, source/drain electrodes, and a substrate. When the electrons ate trapped the silicon nitride film, the threshold voltage of the MONOS transistor increases, compared with a case that the electrons are not trapped in the silicon nitride film. Oppositely, the threshold voltage decreases when the trapped electrons are pulled out from the silicon nitride film. The MONOS transistor can store data of “1” and “0” in nonvolatile manner by using the change in such a threshold voltage.

The memory using an element that traps the electric charge like this MONOS transistor is called “Charge Trapping Memory”. The following are known, for example, as a technique concerned with the charge trapping type memory.

Japanese Laid Open Patent Application (JP-P2005-197425A) discloses a nonvolatile memory device, in which a first trench is formed on a surface of a semiconductor substrate, and a second trench is formed in a bottom of the first trench according to a nonvolatile memory disclosed in patent document 1. A first active region is formed adjacently to the first trench in the surface of the semiconductor substrate. On the bottom surface of the first trench, a second active region is formed adjacently to the second trench. A third active region is formed in the bottom of the second trench. An ONO film is formed on the surface of the first trench and the second trench, and a gate electrode is formed on the ONO film.

Japanese Laid Open Patent Application (JP-2001-77219A) disclosed a nonvolatile memory device, which has a semiconductor substrate of a first conduction type, and first and second diffusion regions of a second conduction type. A plurality of trenches are formed in the semiconductor substrate in parallel to each other. The first diffusion region is formed in the bottom of the trench. On the other hand, the second diffusion region is formed in a surface portion of the semiconductor substrate other than the trench. An Q)NO film is formed in the surface of the semiconductor substrate, and a conductive layer is formed on the ONO film to intersect with the plurality of trenches.

U.S. Pat. No. 6,255,166 discloses a method for manufacturing a nonvolatile memory device. The nonvolatile memory device has a first gate insulating film, a second gate insulating film, a first gate electrode formed on the first gate insulating film, and a second gate electrode formed on the second gate insulating film. The first gate insulating film is formed on a first channel formation region adjacent to a source region, and the second gate insulating film is formed on a second channel formation region adjacent to a drain region. The second gate insulating film is a laminated film( that can trap electric charge such as an ONO films. Thus, one memory cell is composed from a plurality of transistors.

The technique that can furthermore achieve the fineness of the memory cell of the nonvolatile semiconductor memory device is desired. For example, in the case of the above-described patent document 3, some length is necessary for each a gate length L1 to the first gate electrode and a gate length L2 to the second gate electrode in order to prevent the punch through in each transistor. Therefore, it is physically difficult to reduce the gate length (L1+L2) of the memory cell transistor extremely. In that case, even if the fine processing technique develops, there is a possibility that an amount corresponding to it cannot reduce the size of the memory cell.

### SUMMARY OF THE INVENTION

In an aspect of the present invention, a nonvolatile semiconductor memory device includes a semiconductor substrate having trenches formed to extend in parallel; a first electrode formed on the semiconductor substrate through an insulating film in each of the trenches; a second electrode formed on the first electrodes and the semiconductor substrate through the insulating film; a diffusion layer formed in a predetermined depth of the semiconductor substrate in association with each of the trenches,; and a trap film as a part of the insulating film configured to trap electric charge. A channel region is formed between adjacent two of the diffusion layers without any diffusion layer.

Here, the diffusion layer may be formed in each of inter-trench portions of the semiconductor substrate.

Also, the trap film may be formed between the second electrode and said a sidewall of the trench.

Also, the diffusion layer may be formed in each of portions of the semiconductor substrate under the trenches.

Also, the trap film may he formed between the first electrode and the sidewall of the trench at least.

Also, a portion of the insulating film other than the trap film may he different from the trap film in composition.

Also, the first electrode may be formed to fill a whole of the trench, and the second electrode may be formed on the semiconductor substrate through the insulating film.

Also, the trenches may be formed to extend in a first direction, and the diffusion layer may be formed to extend in the first direction. The first electrode may be formed to extend in the first direction, and the second electrode may be formed to extend in a second direction orthogonal to the first direction.

Also, the trap film may include a laminate film of an oxide film and a nitride film. Instead, the trap film may be an insulating film in which a metal dot is formed.

In another aspect of the present invention, a nonvolatile semiconductor memory device includes a semiconductor substrate having trenches; a source and a drain formed in the semiconductor substrate on both sides of a first trench of the trenches to sandwich the first trench; a word gate provided on the semiconductor substrate through an insulating film in a bottom of the first trench; a control gate formed oil the semiconductor substrate through the insulating film to fill a remaining portion of the first trench; and a trap film formed between the control gate and the semiconductor substrate in the first trench as a part of the insulating film to trap electric charge.

Here, a channel region between the source and the drain may be formed along the first trench.

Also, the source may be connected with a first bit line extending in a first direction, and the drain may be connected with a second bit line extending in the first direction. The word gate may be connected with a first word line extending in the first direction, and the control gate may be connected with a second word line extending in a second direction orthogonal to the first direction.

In still another aspect of the present invention, a nonvolatile semiconductor memory device includes a semiconductor substrate having first and second trenches which are adjacent to each other; a source formed in the semiconductor substrate in the first trench; a drain formed in the semiconductor substrate in the second trench; a first control gate formed on the semiconductor substrate through an insulating film in a bottom of the first trench; a second control gate formed on the semiconductor substrate through the insulating film in a bottom of the second trench; a word gate formed the semiconductor substrate and the first and second control gates; and a trap film formed between the first control gate and the semiconductor substrate in the first trench and between the second control gate and the semiconductor substrate in the second trench as a part of the insulating film to trap electric charge.

Here, a channel region between the source and the drain may be formed along an inter-trench portion of the semiconductor substrate.

Also, the source may be connected with a first bit line extending in a first direction, arid the drain may be connected with a second bit line extending in the first direction. The first control gate may be connected with a first word line extending in the first direction, the second control gate may be connected with a second word line extending in the first direction, and the word gate may be connected with a third word line extending in a second direction orthogonal to the first direction.

Also, a portion of the insulating film other than the trap film may be different from the trap film. Instead, the trap film may include a laminate film of an oxide film and a nitride film. Instead, the trap film may be formed as the part of the insulating film in which a metal dot is formed.

According to the present invention, the size of a memory cell can be made small in correspondence to the development of the fine processing technique.

### BRIEF DESCRIPTION OF THE DRAWINGS

FIG. 1 is a plan view showing the structure of a nonvolatile semiconductor memory device according to a first embodiment of the present invention;

FIGS. 2A and 2B are cross sectional views showing the sectional structures of the nonvolatile semiconductor memory device in the first embodiment along a line A-A′ and a line B-B′ of FIGS. 1;

FIG. 3 is a diagram showing a program operation of the nonvolatile semiconductor memory device in the first embodiment;

FIG. 4 is a diagram showing an erasing operation of the nonvolatile semiconductor memory device in the first embodiment;

FIG. 5 is a diagram showing a reading operation of the nonvolatile semiconductor memory device in the first embodiment;

FIGS. 6A and 6B are cross-sectional views showing modifications of the nonvolatile semiconductor memory device according to the first embodiment;

FIG. 7 is a diagram symbolically showing a memory cell of the nonvolatile semiconductor memory device in the first embodiment;

FIG. 8 is a circuit diagram showing the configuration of a memory cell array in the nonvolatile semiconductor memory device according to the first embodiment;

FIG. 9 is a table showing voltages in various operations of the nonvolatile semiconductor memory device operates according to the first embodiment;

FIGS. 10A to 10E are cross sectional views showing a method of manufacturing the nonvolatile semiconductor memory device according to the first embodiment;

FIG. 11 is a cross sectional view showing a further modification example of the nonvolatile semiconductor memory device according to the first embodiment;

FIG. 12 is a plan view showing the structure of the nonvolatile semiconductor memory device according to a second embodiment of the present invention;

FIGS. 13A and 13B are cross sectional views showing sectional structures along a line A-A′ and a line B-B′ in FIG. 12;

FIG. 14 is a diagram showing a program operation of the nonvolatile semiconductor memory device in the second embodiment;

FIG. 15 is a diagram showing an erasing operation of the nonvolatile semiconductor memory device in the second embodiment;

FIG. 16 is a diagram showing a reading operation or the nonvolatile semiconductor memory device in the second embodiment;

FIGS. 17A and 17B are cross sectional views showing modification examples of the nonvolatile semiconductor memory device in the second embodiment;

FIG. 18 is a circuit diagram showing the structure of a memory cell array in the nonvolatile semiconductor memory device according to the second embodiment; and

FIG. 19 is a table showing voltages in various operations of the nonvolatile semiconductor memory device operates according to the second embodiment.

### DESCRIPTION OF THE PREFERRED EMBODIMENTS

Hereinafter, a nonvolatile semiconductor memory device and a method for manufacturing the nonvolatile semiconductor memory device according to the present invention will be described with reference to the attached drawings. The nonvolatile semiconductor memory device according Lo the present invention is a charge trapping type memory.

### First Embodiment

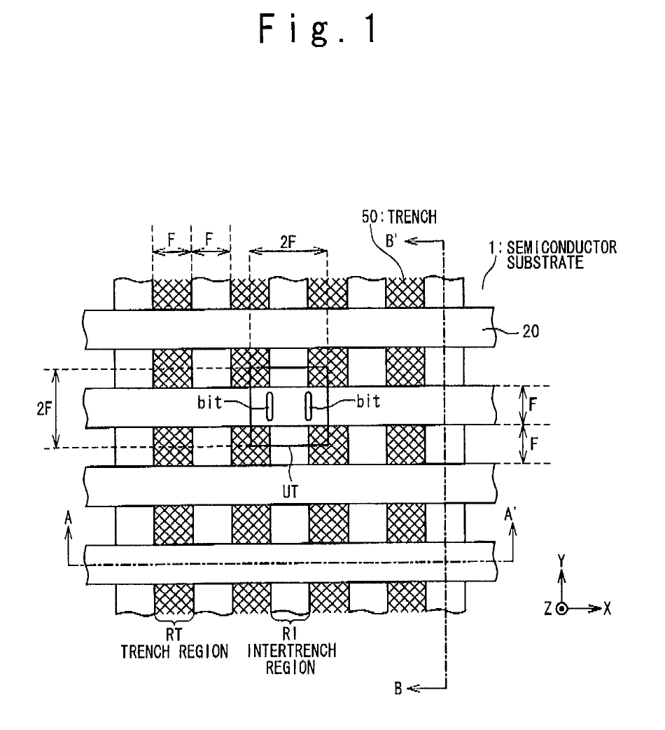

FIG. 1 is a plan view showing the structure of the nonvolatile semiconductor memory device according to the first embodiment of the present invention. The nonvolatile semiconductor memory device is provided for a substrate 1 such as a silicon substrate. Here, a Z direction is defined as a perpendicular direction to the principal plane of the substrate 1. X and Y directions are directions orthogonal to the Z direction, and form a parallel plane to the principal plane of the substrate 1. Moreover, the X and Y directions are orthogonal to each other.

A plurality of trenches 50 are formed in the substrate 1 to extend in the Y direction in parallel. In other words, each of the plurality of trenches 50 is formed in a stripe manner. Hereinafter, a region where the trenches 50 are formed in the substrate 1 will be referred to as a “Trench region RT”. On the other hand, a region where the trenches 50 are not formed, that is, a region between trenches 50 will be referred to an “Inter-trench region RI”. The inter-trench region RI has a strip shape as well as the trench region RT and they appear alternately. In addition, a plurality of gate electrodes 20 (second gate electrode) to be described later are formed on the substrate 1 to extend in the x direction in parallel.

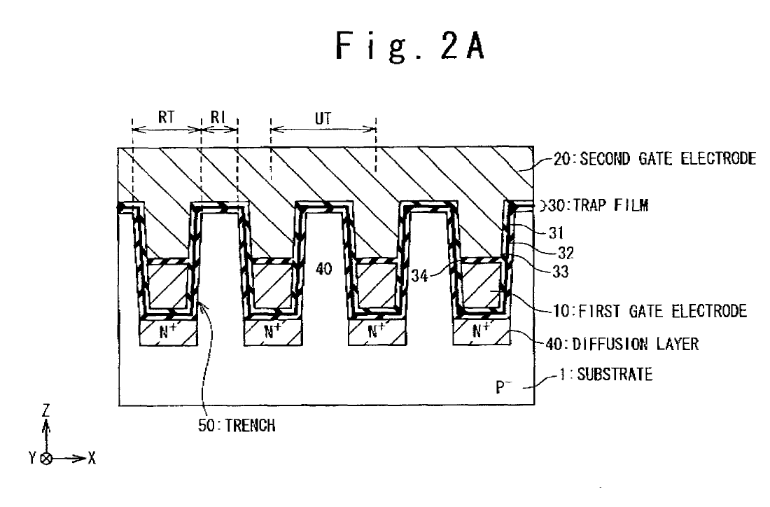

FIGS. 2A and 2B show cross sectional view showing the configurations of the nonvolatile semiconductor memory device along the line A-A′ and the line B-d′ in FIG. 1. As shown in FIGS. 2A and 2B, a first gate electrode 10 is provided for the trench region RT. More specifically, the first gate electrode 10 is arranged in the bottom of each trench 50 to extend in the Y direction. On the other hand, the second gate electrode 20 is formed to extend in the X direction that is orthogonal to the Y direction. This second gate electrode 20 is provided above the first gate electrode 10, and a part of the second gate electrode 20 falls in the trench 50. An insulation film 34 is provided between the first gate electrode 10 and the second gate electrode 20. An interlayer insulating film 60 is formed between the adjacent two of the second gate electrodes 20. Moreover, a trap film 30 is formed between the substrates 1 and a set of the first and second gate electrodes 10 and 20 in FIGS. 2A and 2B. In other words, the trap film 30 is formed on the surface of the substrate 1 including an inner wall of the trench 50. Although this trap film 30 is an insulating film, the trap film 30 has a structure to trap electric charge easily. For example, the trap film 30 is an ONO film in which an oxide film 31, a nitride film 32, and an oxide film 33 are sequentially laminated. In this case, the electric charge may be trapped in the nitride film 32. A silicon dioxide film is exemplified as the oxide film. Moreover, the oxide film such as an aluminum oxide film, a hafnium oxide film, a tantalum oxide film, a titanium oxide film, a zirconia oxide film. Silicates that the silicon element with them are mixed may be used. Moreover, only the ON film, the ONON film or the nitride film may be used as the trap film 30. Furthermore, the trap film 30 may be an insulating film in which a plurality of island shaped metal dots are formed internally. In this case, the electric charge jumps into tile plurality of metal dots. The metal dot is, for example, a silicon dot formed of silicon. Moreover, the metal dot may be a grain of metal such as tungsten, cobalt, titaniums, and nickel.

Furthermore, diffusion layers 40 (impurity diffusion regions) as source/drain extend in the Y direction in the substrate 1. For example, the diffusion layer 40 is formed with impurity of an N⁺ type for the substrate 1 of a P⁻ type. As shown in FIG. 2A, the diffusion layer 40 is formed in the surface neighborhood of the substrate 1 corresponding to a bottom surface of the trench 50. In other words, according to the present embodiment, the diffusion layer 40 is formed only under the bottom surface of each trench 50, and not formed in the inter-trench region RI. The diffusion layer 40 is not provided separately for an upper side and under side of the trench 50, but provided at the same level for the Z direction (a direction of the substrate depth). In addition, one diffusion layer 40 might become a source, and might become a drain. As for a pair of the diffusion layer 40 of a MOS transistor, when one side is a source (drain), other side becomes a drain (source). In this specification, the source/drain layer means one diffusion layer 40 that functions as a source or a drain of the MOS transistor.

Moreover, a region that corresponds to the region (a unit region) shown by reference numeral UT in FIG. 1 is shown in FIGS. 2A and 2B. It could be understood that the structure of the unit region UT is repeatedly arranged.

It should be noted that the respective sizes are as follows in an example of the above-described structure: a depth of the trench 50=110 nm; a width of the bottom surface of the trench 50 in the X direction=60 nm; a width of a slope in the trench 50 in the X direction=10 nm; a width of inter-trench region RI in the X direction=60 nm; a thickness of the diffusion layer 40 in the Z direction=20 nm to 30 nm; each thickness of the oxide film 31, the nitride film 32 and the oxide film 31 in the trap film 30=5 nm; a thickness of the first gate electrode 50 in the Z direction=about 50 nm; and a thickness of the insulating film 34=10 nm.

Next, writing/erasing/reading operations of the nonvolatile semiconductor memory device according to the first embodiment will be described.

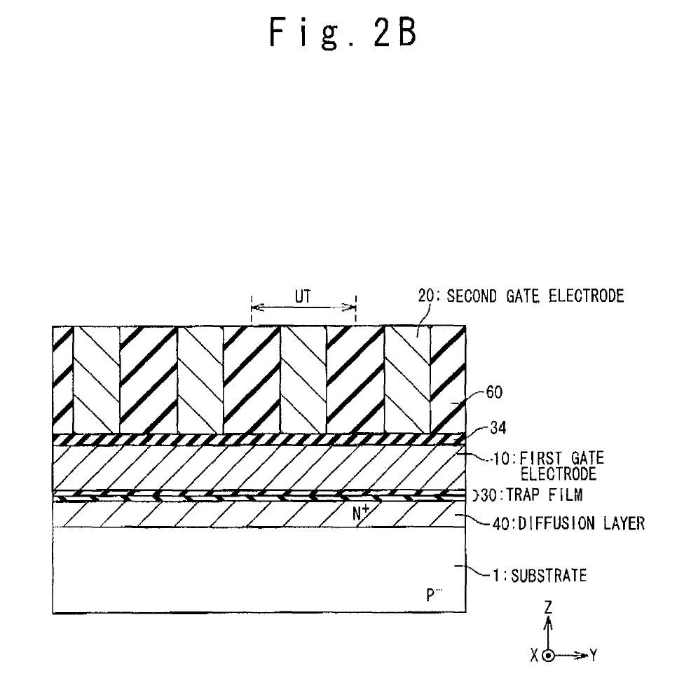

FIG. 3 is a diagram for explaining a program operation of the nonvolatile semiconductor memory device in the first embodiment. Two adjacent trenches 50 shown in FIG. 3 will respectively he referred to as a first trench 50-1 and a second trench 50-2. A first gate electrode 10-1 provided for the bottom of the first trench 50-1 will be referred to as a “first control gate CG1”. On the other hand, a first gate electrode 10 2 provided for the bottom of the second trench 50-2 will be referred to as a “second control gate CG2”. Moreover, a second gate electrode 20 provided above the first control gate CG1 and the second control gate CG2 will be referred to as a “word gate Ware. Moreover, it is assumed that the diffusion layer 40 (BL1) formed under the bottom of the first trench 50-1 is a source 40s. The first control gate CG1 is provided on the bottom of the first trench 50-1, and is opposed to the source 40s. On the other hand, it is assumed that the diffusion layer 40 (BL2) formed under the bottom of the second trench 50-2 is a drain 40d. The second control gate CG2 is provided on the bottom of the second trench 50-2, and is opposed to the drain 40d. The source 40s and the drain 40d function as a pair, and the electrons from the source 40s is injected into the drain 40d. As shown in FIG. 3, the word gate WG covers at least a part of the substrate surface (containing the sidewall of the trench 50) between the first control gate CG1 and the second control gate CG2. In other words, the source 40s, the first control gate CG1, the word gate WG, and the second control gate CG2 and the drain 40d are provided in this order along the surface of the substrate 1. Therefore, a channel region CH is formed along the side surface of the first trench 50-1, the substrate surface between the trenches, and the side surface of the second trench 50-2.

The writing operation is performed by a Channel Hot Electron (CHE) system. For example, the voltages of 0V, 1.8V, 1.8V, +5V and +5V are applied to the source 40s, the first control gate CG1, the word gate WG, the second control gate CG2 and the drain 40d, respectively. At this time, the electrons are emitted from the source 40s, and move toward the first control gate CG1 and the word gate WG along the sidewall of the first trench 50-1. Then, after the electrons get around the substrate surface in the inter-trench, the electrons move toward the second control gate CG2 and the drain 40d along the sidewall of the second trench 50-2 (referring of the arrow shown in FIG. 3). The electrons accelerated in the neighborhood of the second control gate CG2 and the drain 40d become hot electrons, and the hot electrons arrive to the nitride film over a barrier of the oxide film of the trap film 30. In this case, the electrons are trapped in the trap film 30 (nitride film) between the second control gate CG2 and the side surface of the second trench 50-2. As a result, the threshold voltage of a transistor having the second control gate CG2 increases. In other words, the trap film 30 between the second control gate CG2 and the side surface of the second trench 50-2 plays a role as a storage region (bit) BIT2 that stores data. Here, the generation efficiency of the hot electrons rises very high according to the structure in the present embodiment. The reason will be described as follows, A potential of a channel CH opposing to a word gate WG (1.8V) and a potential of a channel CH opposing to the second control gate CG2 (+5V) are largely different. In other words, the potential of the channel CH changes rapidly in a point PG in the vicinity of the boundary between the word gate WG and the second control gate CG2. Since the potential is changed within a small distance, an intense electric field is generated in the point PG. Therefore, the hot electrons are generated easily in neighborhood of the point PG. Moreover, the electrons may become the hot electrons by being accelerated in a depletion layer in neighborhood of the drain 40d (+5V) as well as usual CHE. Thus, the hot electrons may be generated through two mechanisms at the same time. As a result, the generation efficiency of the hot electrons rises very high. Since the generation efficiency is high, a write current required for the writing operation remarkably becomes small. The injection of the hot electrons generated in the above-described point PG neighborhood might be called “Source Side Injection (SSI)”. The SSI is a phenomenon depending on the arrangement structure of the word gate WG and the control gate CG along the channel CH in the present embodiment.

Next, a case that the distribution of the applied voltage becomes an opposite state will be considered. In other words, the voltage of +5V is applied to the first control gate CG1 and the diffusion layer 40 (BL1) opposiitg to CG1, and the voltages of 1.8V and 0V are applied to the second control gate CG2 and the diffusion layer 40 (BL2) opposing to the second control gate CG2, respectively. In this case, the diffusion layer 40 on the Side of the first trench 50-1 becomes the drain 40d, and the diffusion layer 40 on the side of the second trench 50-2 becomes a source 40s. At this time, the electrons are injected into the trap film 30 (nitride film) between the first control gate CG1 and the side surface of the first trench 50-1. In other words, the trap film 30 between the first control gate CG1 and the side surface of the first trench 50-1 plays a role as a storage region (bit) BIT1 that stores data. Thus, two bits (BIT1, BIT2) are stored in the unit region UT according to the structure in the present embodiment.

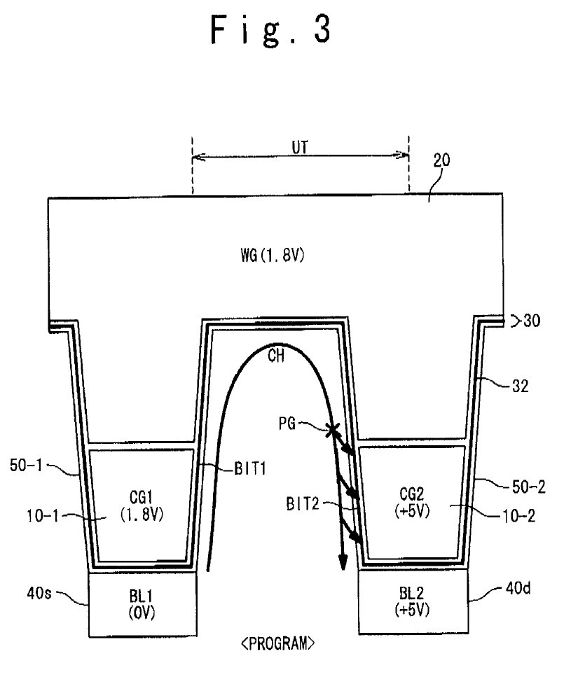

Next, the erasing operation will be described referring to FIG. 4. FIG. 4 is a diagram showing an erasing operation of the nonvolatile semiconductor memory device in the first embodiment. Here, the erasing operation of the data stored in the storage area BIT2 will he considered as an example.

The erasing operation is performed in a Hot Hole Injection (HHI) system. For example, the voltage of 0V is applied to the word gate WG, and the diffusion layer 40 (BL1) and the first control gate CG1 on the side of the first trench 50-1. Moreover, the voltages of +5V and −5V are applied to the diffusion layer 40 (BL2) and the second control gate CG2 on the side of the second trench 50-2, respectively. In this case, a potential changes rapidly in a narrow region between the second control gate CG2 and the diffusion layer 40, and an intense electric field is generated in neighborhood of the point PH, The charged carriers (electrons and holes) naturally generated are accelerated by the intense electric field, to cause impact ionization. A new pair of electron and hole is generated through this impact ionization. When the number of pairs to be generated is more than the number of pairs to be lost, a lot of electrons and holes of the high energy are generated around the point PH because of avalanche breakdown. The holes of the high energy are attracted to the second control gate. CG2 to which the negative voltage (−5V) is applied. The holes of the high energy jumps into the Legion of the nitride film where the electrons are trapped, and as a result, the threshold voltage of the transistor having of the second control gate CG2 decreases. That is, the data of the storage region BIT2 is erased.

A case that the data of the storage region BIT2 is “over-erased” will be considered. In that case, the threshold voltage becomes negative, and there is a possibility that the transistor having the second control gate CG2 always turns “ON”. However, according to the present embodiment, since the word gate WG is provided, a region between the source and the drain is prevented from being set to a conductive state. Thus, the word gate WG plays a role to eliminate the problem of over-erasing which is particular to the flash memory.

In addition, the voltages of −5V and +5V are respectively applied to the first control gate CG1 and the diffusion layer 40 on the side of the first trench 50-1 for the erasing operation to the storage region BIT1. Moreover, the erasing operation by using an FN current may be performed by applying a negative voltage (−15V) to the control gate CG, so that the voltage of the diffusion layer 40 is set to 0V. However, since the above-described HHI system can suppress the applied voltage to a low voltage, the HHI system is more suitable.

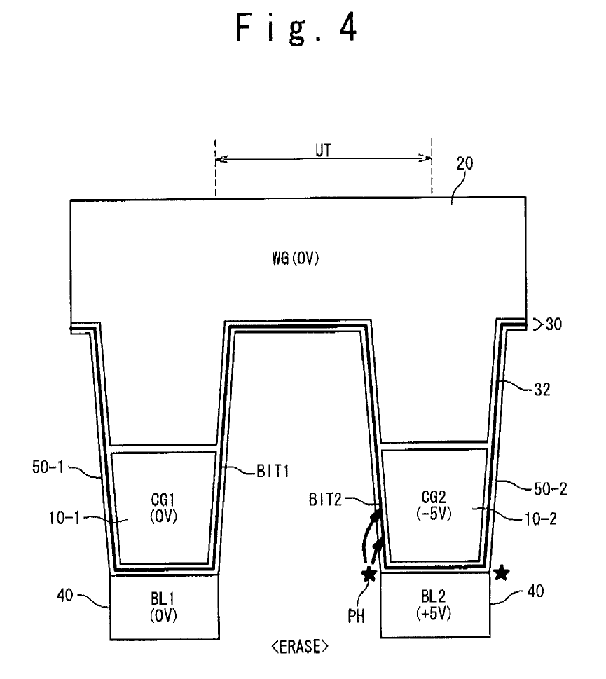

Next, the reading operation will be described referring to FIG. 5. FIG. 5 is a diagram showing a reading operation of the nonvolatile semiconductor memory device in the first embodiment. Here, a case where the data stored in the storage region BIT2 is read out will be considered as an example.

For example, the voltage of 1.8V is applied to the word gate WC, and the first and second control gates CG1 and CG2. Furthermore, the voltage of 1.8V is applied to the diffusion layer 40 (BL1) on the side of the first trench 50-1, and the voltage of 0V is applied to the diffusion layer 40((BL2) on the side of the second trench 50-2. In this case, the diffusion layer 40 on the side of the second trench 50-2 becomes a source 40s, and the diffusion layer 40 on the side of the first trench 50-1 becomes a drain 40d. Whether or not the channel extends from the source 40s depends on the threshold voltage of the transistor having the second control gate CG2. That is, whether or not the transistor turns “ON” depends on the data of the storage region BIT2. The channel extends to the neighborhood of the first control gate CG1 if the transistor turns “ON”, Here, whether or not the transistor having the first Control gate CG1 turns “ON” depends on the data in the storage region BIT1. However, since a depletion layer extends from the drain 40d (1.8V) to the neighborhood of the first control gate CG1 (1.8V), the electrons can jump into the drain 40d as long as the channel extends from the source 40s to the neighborhood of the first control gate CG1, In other words, whether or not the electric current flows does not depends on the data in the storage region BIT1, and it depends only on the data in the storage region BIT2. Therefore, the data of the storage region BIT2 can be determined by detecting the drain current. It only has to set the voltage of the diffusion layer 40 on the side of the storage region BIT1 to 0V in order to determine the data in the storage region BIT1.

The writing/erasing/reading operations to the storage regions BIT1 and BIT2 are achieved as described above. The above-described word gate WG is a gate (select gate) to permit the access to the storage region. Data is not stored in the transistor having the word gate WG. On the other hand, the control gate CG is a gate that is arranged adjacently to the storage region, and is used to control the writing/erasing/reading operations to the storage region. Data is stored in the transistor having the control gate CG. In that sense, the above-described trap film 30 only has to be formed at least between the control gates CG (CG1, CG2) and the side surface of the trench 50. In case of the present embodiment, the control gate CC, is the first gate electrode 10 provided for the region opposing to the diffusion layer 40 in the trench 50. Therefore, the trap film 30 only has to be formed between the first gate electrode 10 and the side surface of the trench 50 at least.

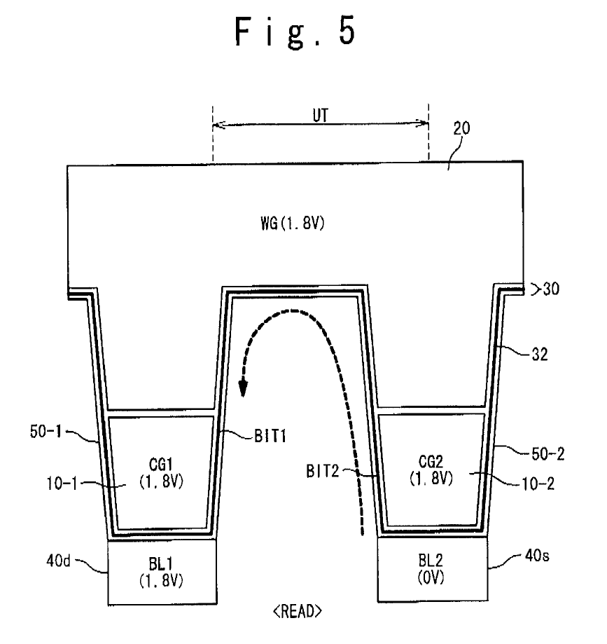

For example, the trap film 30 is formed only between the first gate electrode 10 and the side surface and bottom surface of the trench 50 in FIG. 6A. Between the second gate electrode 20 and the surfaces of the substrate 1, the trap film 30 is not formed, and a mere insulating film 34 that is not the trap film 30 is formed. The insulating film 34 is, for example, a silicon dioxide film of a monolayer, and the electric charge is not trapped. Moreover, the trap film 30 is formed only between the first gate electrode 10 and the side surface of the trench 50 in FIG. 6B. The insulating film 34 that does not trap the electric charge is formed between the second gate electrode 20 and the surface of the substrate 1. Moreover, the insulating film 35 that does not trap the electric charge is formed between the first gate electrode 10 and the bottom of the trench 50. In case of the structure of shown in FIG. 6A or FIG. 6B, since the electrons are not trapped around the word gate WG, the threshold voltage of the transistor having the word gate WG does not vary. This is very preferable from the viewpoint of the stability of a device operation.

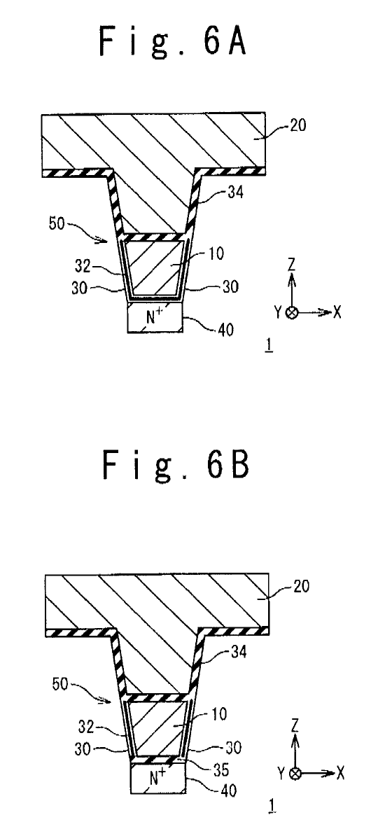

The described above structure (memory cell) of the unit region UT is as shown in FIG. 7. As shown in FIG. 7, the structure of the memory cell according to the present embodiment is a transistor structure with three gates (CG1, WG, CG2), and 2 bits are included in it. One side bit (BIT1) is provided for the first control gate CG1, and the other bit (BIT2) is provided for the second control gate CG2. The word gate WG is provided between the first and second control gates CG1 and CG2, and those three gates are consecutively provided without source/drain.

The gate lengths of three gates CG1, WG, and CG2 are assumed to be Lcg1, Lwg, and Lcg2, respectively. A length is necessary for each of the three gates CG1, WG, and CG2 to prevent punch-through phenomenon in each transistor. Therefore, a total gate length L (=Log1+Lwg+Lcg2) cannot be extremely shortened. Here, according to the present embodiment, a source/drain 40 is not provided separately for the upper side and under side in the trench 50 but is provided at a same level for the Z direction (the direction of the substrate depth). Therefore, the total gate length L can be secured for the 2 directions of the horizontal direction (direction of X) and the vertical direction (direction of Z). In other words, the total gate length t can be secured in not a straight line but a polygonal line. As a result, it is possible to reduce the region of the memory cell in the X-Y plane while securing the total gate length L (=Lcg1+Lwg+Lcg2).

Referring FIG. 1, it could be understood that the region of the unit region UT is achieved with 4 F² (F: Feature Size). Since 2 bits are included in the unit region UT, the region of one cell can be substantially achieved with 2 F². This is excellent compared with a region (4 F²) of the cell of a usual NAND type flash memory. Thus, it can be understood that the memory cell structure according to the present invention is already excellent on the design. Furthermore, according to the present invention, even if a fine processing technique develops to make parameter F small, the total gate length L can be secured enough as the above described. Therefore, it can be avoided that the device cannot be achieved due to the dissatisfaction of the total gate length L. In the conventional technique, since the total gate length L is secured only by the straight line, there is possibility that the adoption of a fine process is difficult because of the constraint that the total gate length L is dissatisfied. According to the present invention, the memory cell can be achieved without receiving such a constraint. That is, it is possible Lo reduce the size of the memory cell in accordance with the development of the fine processing technique.

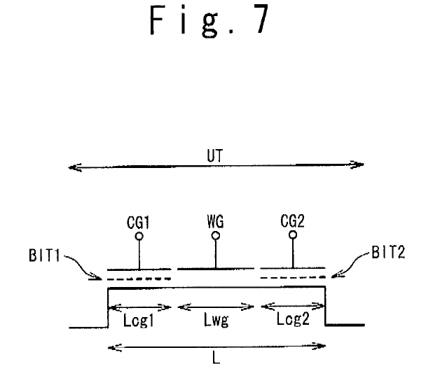

FIG. 8 shows an example of a memory cell array by using the memory cells shown in FIG. 7. In FIG. 8, a plurality of memory cells are arranged in a matrix manner. A plurality of bit lines BL-1 to BL5 extend in the Y direction. A plurality of word lines CG-1 to COS extend to the Y direction. Another plurality of word lines WC0 to WG3 extend in the X direction. The source 40s and the drain 40d in a certain memory cell are connected with each of the adjacent first bit line (for example, BL1) and second bit line (for example, BL2). The first control gate CG1 and the second control gate CG2 are connected with each of the adjacent first word line (for example, CG1) and second word line (for example, CG2). The word gate WG is connected with the third word line (for example, WG1) that extends in the X direction.

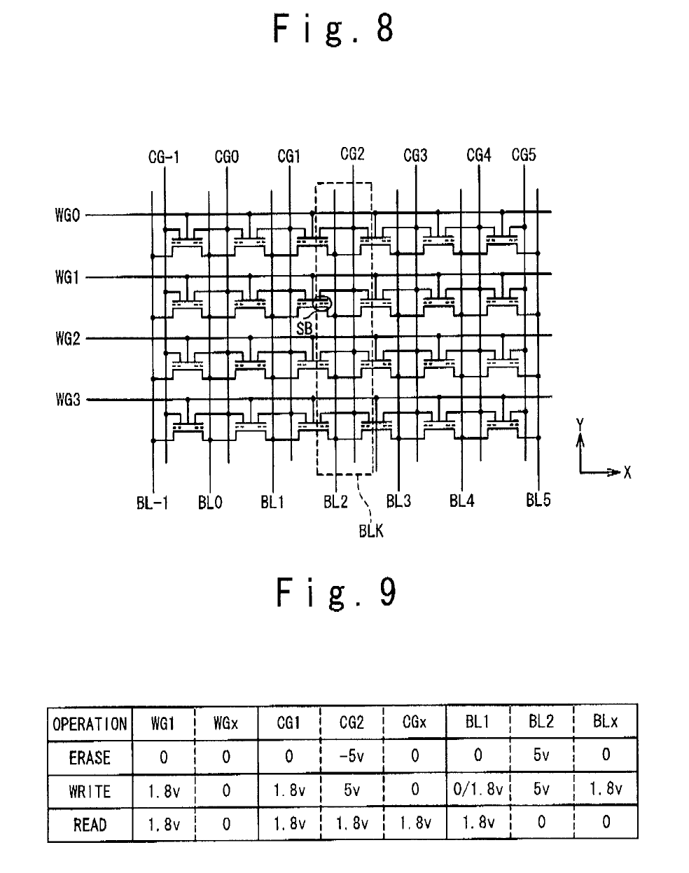

The memory cell including a selection bit SB specified by a circle in FIG. 8 is connected with the bit lines BL1 and BL2, and the word lines CG1, CG2 and WG1. The applied voltage in the erasing/writing/reading operations to the selection bit SB is shown in FIG. 9 in summarized manner. In FIG. 9, a suffix x indicates other bit lines and other word lines. Details of each operation are as shown in FIGS. 3 to 5. It should be noted that in the erasing operation, the collective erasure is performed of the data of all bits connected to the bit line BL2 (8 bits included in block BLK in FIG. 8). Moreover, after the collective erasure is performed, the writing operation is performed. The voltage applied to the bit line BL1 at the time of the writing operation depends on the write data. When writing operation is necessary, the voltage of the bit line BL1 is set to 0V, and when the writing operation is unnecessary, the voltage of bit line BL1 is set to 1.8V. In other words, the write data “0” or “1” can be controlled according to the voltage of the bit line BL1.

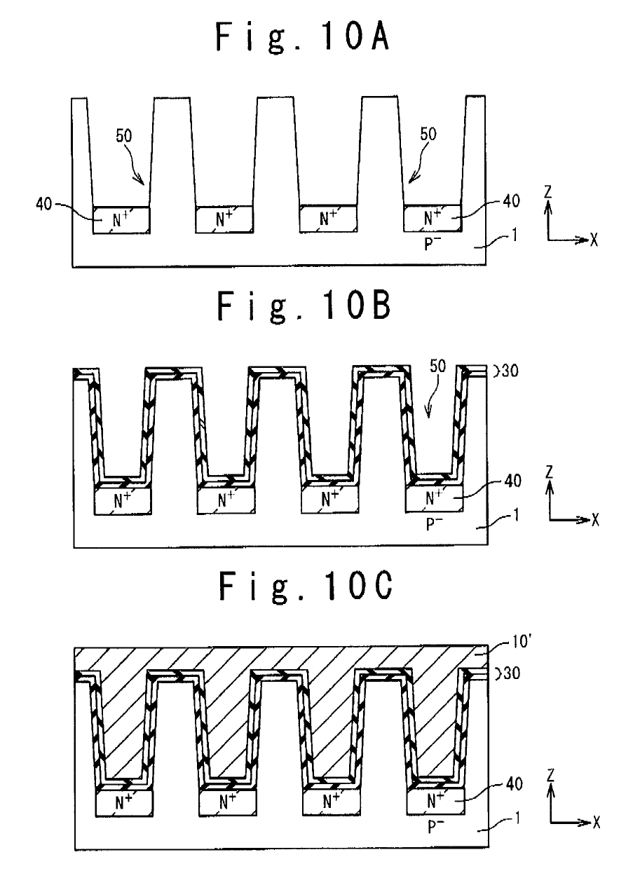

Next, the method of manufacturing the nonvolatile semiconductor memory device will be described. FIGS. 10A to 10E are cross sectional views showing a method of manufacturing the nonvolatile semiconductor memory device according to the present embodiment. The cross sectional structure of FIGS. 10A to 10E is a cross sectional structure along the line A-A′ of FIG. 1, and corresponds to the cross sectional structure of FIG. 2A.

First of all, as shown in FIG. 10A, the plurality of trenches 50 are formed in a P-type semiconductor substrate 1 to extend in the Y direction. Moreover, the N⁺ type diffusion layer 40 is formed under the bottom of each trench 50 through the ion implantation. Here, a mask used when the trench 50 is formed may be used as a mask at the ion implantation.

Next, as shown in FIG. 10B, the trap film 30 is formed on the surface of tile substrate 1 in which the inner wall of each trench 50 is included. More specifically, the silicon oxide film and the silicone nitride film and the silicon, oxide film are laminated in this order.

Next, as shown in FIG. 10C, a polysilicon film 10′ is formed on the whole region. The trenches 50 are completely filled with the polysilicon film 10′. Subsequently, an etching-back to the polysilicon film 10′ is performed. As a result, as shown in FIG. 10D, the first gate electrode 10 is formed in the bottom of each trench 50. This first gate electrode 10 extends in the Y direction as well as the trench 50,

Next, as shown in FIG. 10E, the insulating film 34 is formed on the first gate electrode 10. Then, a polysilicon film 20′ is continuously formed on the whole region. After CMP is performed, the patterning of the polysilicon film 20′ is performed. As a result, the second gate electrode 20 is formed to extend in the X direction.

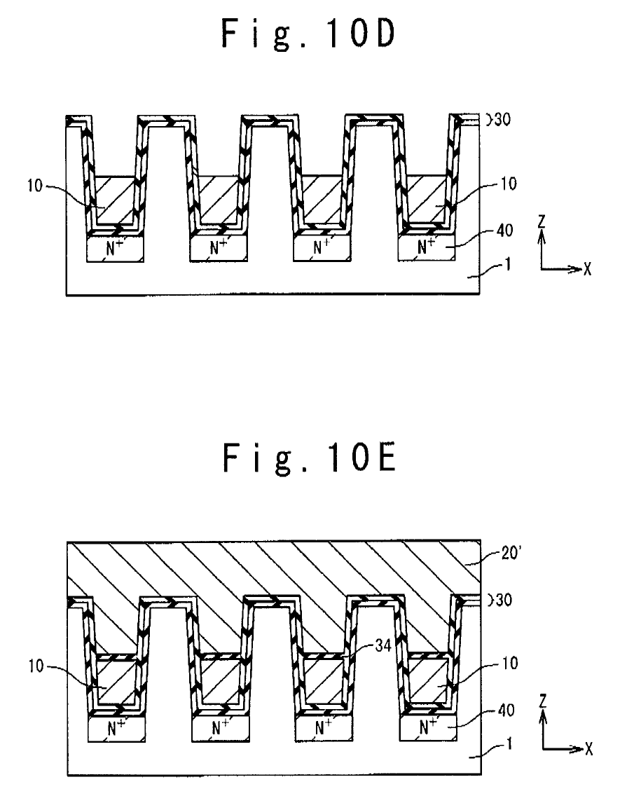

FIG. 11 is a cross sectional view showing a modification example of the nonvolatile semiconductor memory device according to the present embodiment. In FIG. 11, the first gate electrode 10 is formed to till the trench 50 overall. In other words, the upper surface of the first gate electrode 10 is almost coincident with the principal surface of the substrate 1. Then, the second gate electrode 20 is formed oil the principal surface of the first gate electrode 10 and the substrate 1 through the insulating film 34. In other words, the second gate electrode 20 is formed above the principal surface of the substrate 1, and does not fall in the trench 50. In case of the example shown in FIG. 11, there is an advantage that the manufacturing method is simplified more than the example shown in FIGS. 10A to 10E. It is also possible to adopt the structure shown in FIG. 11 if the gate length Lwg to the second gate electrode 20 (word gate WG) is enough, in other words, if the distance between the trenches 50 is enough.

According to the present embodiment, the two gates of the control gate CG and the word gate WC are used. The effect of it is as follows. First of all, since the word gate WG is provided, the conduction between the source and the drain of a non-selection cell can be completely turned off. Therefore, even if a threshold voltage Vtcg to the control gate CG becomes negative due Lo the over-erasing, any leakage current is prevented from flowing from the non-selection cell to a bit line. As a result, correctly sensing the drain current from the selection cell becomes possible. The over-erasing problem particular to the flash memory is structurally eliminated by the word gate WG.

Moreover, since the word gate WG and the control gate CG are arranged along the channel, the Source Side Injection (SSI) is caused in addition to the usual CHE injection. Since the generation efficiency of the hot electrons is very high, the voltage and the current required for the writing operation are reduced. More specifically, the writing operation is possible in the write current of about 1/100 of a usual write current. Therefore, the writing operation can be performed on the plurality of memory cells at a same time. Or, the charge pump for generating the write voltage can be made small. In the former case, the effect of improvement of the write speed is achieved, and, in the latter case, the effect of reduction of the area is achieved,

Moreover, the first control gate CG1 and the second control gate CG2 are provided for both sides of the word gate WG. As a result, 1 bit (BIT1, BIT2) can be stored in either side of the word gate WG. Since 2 bits are stored in the unit region UT (4 F²), the area for one cell can be substantially achieved with 2 F². This is excellent compared with the area (4 F²) of the cell of the usual NAND type flash memory.

Furthermore, according to the present embodiment, the trench 50 is provided in the substrate 1, and the source/drain regions 40 are provided at a same level in the Z direction (the director of the substrate depth). The source/drain regions 10 are not provided separately for the upper side and under side of the trench 50. The effect of it is as follows. That is, the total gate length L (=Lcg+Lwg+Lcg2) can be secured for the 2 directions of the horizontal direction (X direction) and the vertical direction (Z direction). In other words, the total gate length L can be secured as not a straight line but a polygonal line. Therefore, even if the fine processing technique is developed to make the parameter F small, the total gate length L can be secured enough by adjusting the depth of the trench 50. As a result, even when the miniaturization is achieved in size, it can be avoided that the device cannot be realized due to the dissatisfaction of the total gate length L. That is, the size of the memory cell in accordance with the development of the fine processing technique can be reduced.

### Second Embodiment

Next, the nonvolatile semiconductor memory device according to the second embodiment of the present invention will be described. In the following description, the same reference numerals are assigned to the components similar to those in the first embodiment, and the description thereof will be omitted arbitrarily.

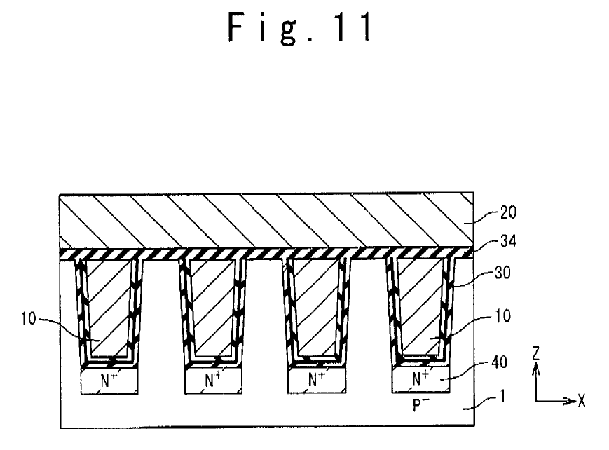

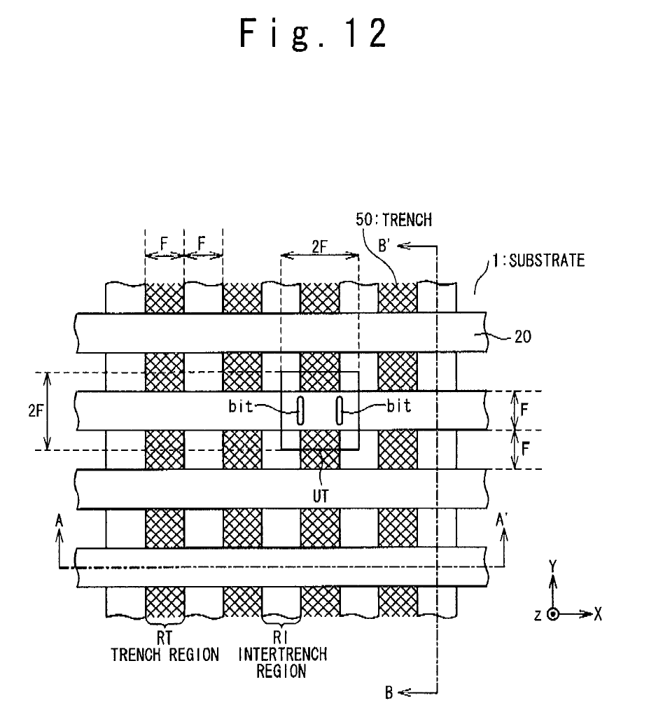

FIG. 12 is a plan view showing the structure of the nonvolatile semiconductor memory device according to the second embodiment. Moreover, FIGS. 13A and 13B are cross sectional view showing the sectional structures along the line A-A′ and the Line B-B′ of FIG. 12. A plurality of trenches 50 are formed in the substrate I in parallel to extend in the Y direction, like the first embodiment. A first gate electrode 10 is provided in the bottom of each trench 50, to extend in the Y direction. On the other hand, a second gate electrode 20 is formed to extend in the X direction that is orthogonal to the Y direction. This second gate electrode 20 is provided above the first gate electrode 10, to cover the substrate surface between the adjacent first gate electrodes 10. A part of the second gate electrode 20 falls into the trenches 50. An insulating film 36 is between the first gate electrode 10 and the second gate electrode 20. Moreover, a trap film 30 is formed between the first and second gate electrodes 10 and 20 and the substrates 1.

Furthermore, diffusion layers 40 are formed as the source/drain to extend in the Y direction in the substrate 1. In the second embodiment, the diffusion layer 40 is not provided separately for the upper side and under side of the trench 50, but the diffusion layers 40 are provided at a same level in the Z direction (the direction of the substrate depth) However, the diffusion layers 40 are formed in neighborhood of the surface of the substrate 1 between the adjacent trenches 50 unlike the first embodiment. In other words, according to the second 5 embodiments the diffusion layer 40 is formed in the substrate surface of the inter-trench region RI, and not formed in the trench region RT. Since the diffusion layer 40 are surrounded by the sidewall of the trench 50 in its side surfaces, a depletion layer 10 only extends in a lower direction. Therefore, even if a high voltage is applied to the diffusion layer 40, the punch-through phenomenon is prevented from occurring between the source and the drain. Moreover, a region corresponding to the unit region UT in FIG. 12 is shown in FIGS. 13A and 13B. It could be understood that the structure in the unit region UT appears repeatedly.

Next the operation of the nonvolatile semiconductor memory device will be described.

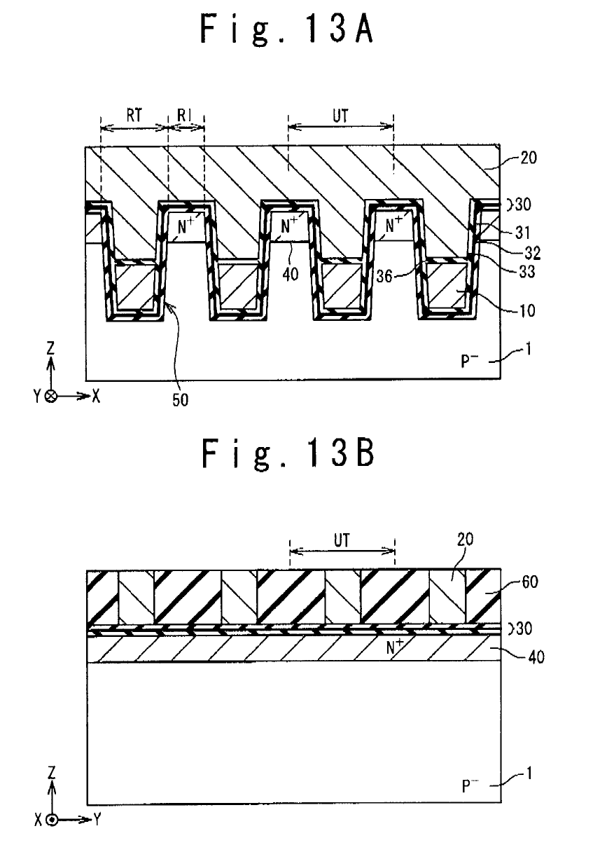

FIG. 14 is a diagram for describing the writing (program) operation, and in particular, schematically shows the cross sectional structure of the unit region UT and the neighborhood thereof. In the second embodiment, the gate electrode opposing to the diffusion layer 40 is the second gate electrode 20, and the second gate electrode 20 plays a role of the “Control gate CG”. In particular, of the parts of the second gate electrode 20 entering the trench 50, the left side of FIG. 14 functions as a “First control gate CGa”, and the right side thereof functions as “second control gate CGb”. These first control gate CGa and the second control gate CGb are formed of the same material, and a same voltage is applied to them. On the other hand, the first gate electrode 10 provided in the bottom of the trench 50 plays a role of the word gate WG. In the trench 50, the first and second control gates CGa and CGb are provided on this word gate WG. The word gate WG is provided on the substrate 1 (inner wall of trench 50) between these first control gate CGa and second control gate CGb. In other words, in the second embodiment, the word gate WG is provided between the first control gate CGa and the second control gate CGb.

As, shown in FIG. 14, the diffusion layers 40 (source/drain) are formed to sandwich the trench 50 in the unit region UT. More specifically, the source 40s and the drain 40d are formed in surface on both sides of the trench 50. The source 40s (BL1) opposes to the first control gate CGa, and the drain 40d (BT2) opposes to the second control gate CGb. Thus, the source 40s, the first control gate CGa, the word gate WC, the second control gate CGb and the drain 40d are provided in this order along the surface of the substrate 1 in the second embodiment. A channel region CH is formed along both sides and the bottom surface of the trench 50.

The writing operation is performed in accordance with the CHE system. For example, the voltages of 0V, 1.8V, +5V and +5V are applied to the source 40s, the word gate WG, the control gate CG and the drain 40d, respectively. Then, the electrons move as shown by the arrow in FIG. 14. The electrons accelerated in neighborhood of the second control gate CGb and the drain 40d becomes the hot electrons, and the hot electrons are injected into the trap film 30, like the first embodiment. In this case, the electrons are trapped in the t-rap film 30 (nitride film) between the second control gate CGb and the side surface of the trench 50. As a result, the threshold voltage of the transistor having the second control gate CGb increases. In other words, the trap film 30 between the second control gate CGb and the side surface of the trench 50 plays a role as a storage region (bit) BIT2 that stores data.

Next, a case where the distribution of applied voltage is opposite will be considered. In this case, the electrons are injected into the trap film 30 (nitride film) between the first control gate CGa and the side surface of the trench 50. In other words, the trap film 30 between the first control gate CGa and the side surface of the trench 50 plays a role as the storage region (bit) BIT1 that stores data. Thus, two bits (BIT1, BIT2) exist in the unit region UT according to the structure of the second embodiment.

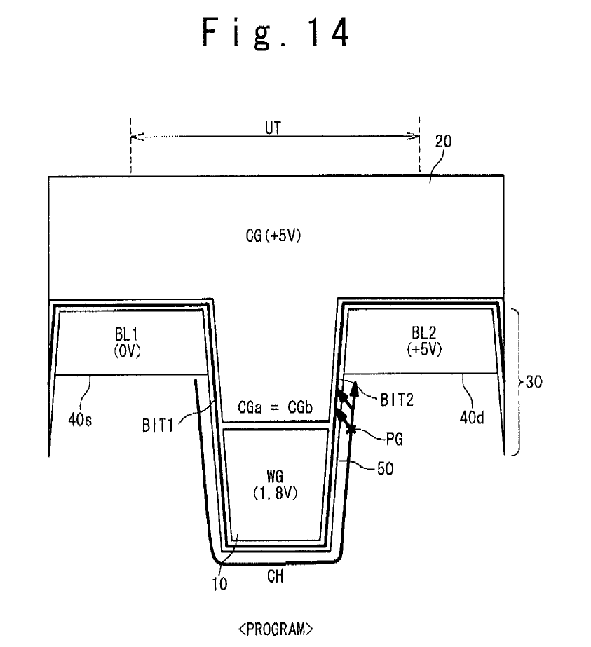

Next, the erasing operation will be described referring to FIG. 15. Here, the erasing operation of the data stored in the storage region BIT2 will be considered as an example. The erasing operation is performed in accordance with the HHI system. For example, the voltage of 0V is applied to the word gate WG and the diffusion layer 40 (BL1) on the side of the BIT1. Moreover, the voltages of +5V and −5V are applied to the diffusion layer 40 (BL2) and the control gate CC on the side of the BIT2, respectively. In this case, an intense electric field is generated in neighborhood of the point PH in the substrate 1, and, as a result, generated high energy holes jumps into a region where the electrons are trapped in the nitride film. As a result, the threshold voltage of the transistor having the second control gate CGb decreases. That is, the data of the storage region BIT2 is erased.

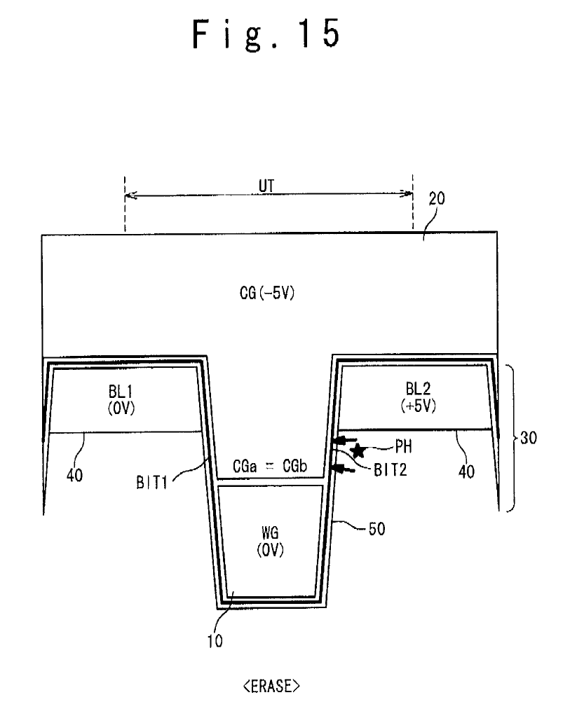

Next, the reading operation will be described referring to FIG. 16. Here, a case that the data stored in the storage region BIT2 is read out will be considered as an example. For example, the voltage of 1.8V is applied to the word gate WC and the control gates CG. Moreover, the voltage of 1.8V is applied to the diffusion layer 40 (BL1) on the side of the BIT1, and the voltage of 0V is applied to the diffusion layer 40 (BL2) on the side of the BIT2. In this case, the diffusion layer 40 on the side of the BIT2 becomes the source 40s, and the diffusion layer 40 on the side of the BIT1 becomes the drain 40d. Whether or not a channel extends from the source 40s depends on the threshold voltage of the transistor having the second control gate CGb. In other words, whether or not the current flows does not depend on the data of the storage region BIT1, and it depends only on the data of the storage region BIT2. Therefore, the data of the storage region BIT2 can be determined by detecting the drain current. The voltage of the diffusion layer 40 on the side of the storage region BIT1 is set to 0V in order to determine the data of the storage region BIT1.

The writing/erasing/reading operations to the storage regions BIT1 and BIT2 are performed as described above. The trap film 30 only has to be formed in at least between the control gate CGs (CGa, CGb) and the side surface of the trench 50, like the first embodiment. In case of the second embodiment, the control gate CG is the second gate electrode 20 provided for the region opposing to the diffusion layer 40. Therefore, the trap film 30 only has to be formed between the second gate electrode 20 and the side surface of the trench 50 at least.

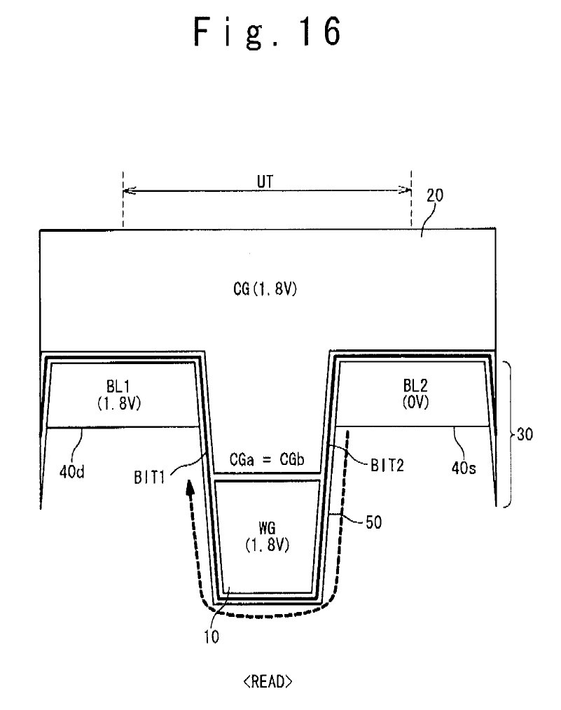

For example, in FIG. 17A, the trap film 30 is formed only between the second gate electrode 20, the side surface of the trench 50 arid the diffusion layer 40. The trap film 30 is not formed between the first gate electrode 10 and the substrate 1, and a mere insulating film 36 that is not the trap film 30 is formed. The insulating film 36 is, for example, a silicon oxide film of a monolayer, and the electric charge is not trapped. Moreover, in FIG. 17B, the trap film 30 is formed only between the second gate electrode 20 and the side surface of the trench 50. The insulating film 36 that does not trap the electric charge is formed between the first gate electrode 10 and the surface of the substrate 1. Moreover, the insulating film 37 that does not trap the electric charge is formed on the upper side of the diffusion layer 40. In case of the structure shown in FIG. 17A or FIG. 17B, since the electrons are not trapped around the word gate WG, the threshold voltage of the transistor having the word gate WG does riot change. This is very preferable from the viewpoint of stability of the device operation.

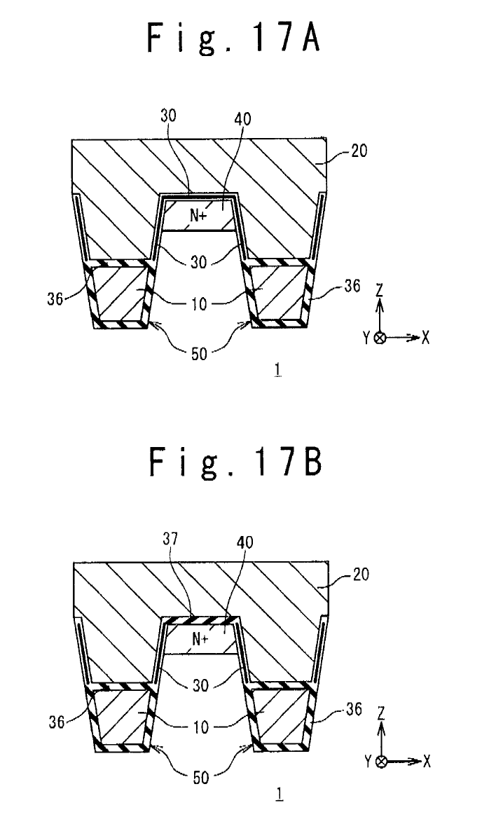

Next, the memory cell and the memory cell array will be described. The structure of the memory cell or the unit region UT is shown as in FIG. 7. FIG. 18 shows an example of the memory cell array of the memory cells according to the second embodiment. In FIG. 18, the plurality of memory cells are located in a matrix manner. A plurality of bit lines BL-1 to BL5 extend in the Y direction. A plurality of word lines WG0 to WG5 extend in the Y direction. A plurality of word lines CG0 to CG3 extend in the x direction. The source 40s and the drain 40d in a certain memory cell are connected with the first bit line (for example, BL1) and the second bit line (for example, BL2), respectively. The word gate WG is connected with the first word line (for example, WG1) extending in the Y direction. The control gates CGs (CGa, CGb) are connected with the second word line (for example, CG1) extending in the X direction.

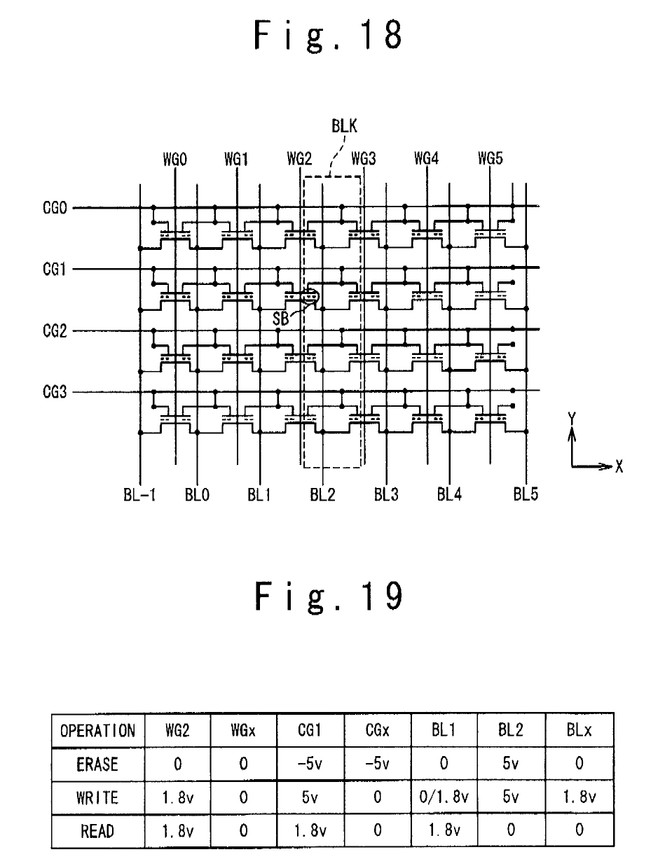

The memory cell including a selection bit SB shown by a circle in FIG. 18 is connected with the bit lines BL1 and BL2, and the word lines WG2 and CG1. The applied voltages in the erasing/writing/reading operations to the selection bit SB are shown in FIG. 19. In FIG. 19, the suffix x indicates other bit lines arid other word lines. Details of each operation are as those shown in FIGS. 14 to 16. In addition, in the erasing operation, it should be noted that the collectively erasing operation is performed to the data of all bits (8 bits in FIG. 18 included in the block BLK) connected to tire bit line BL2. Moreover, after the collectively erasing operation is performed, a writing operation is performed. The voltage applied to the bit line BL1 in the writing operation depends on the write data. When the writing operation is necessary, the voltage of the bit line BL1 is set to 0V, and when the writing operation is unnecessary, the voltage of bit line BL1 is set to 1.8V. In other words, the write data “0” or “1” can be controlled by the voltage of the bit line BL1.

Next, a method of manufacturing the nonvolatile semiconductor memory device according to the second embodiment will be described. The method is almost similar to the manufacturing method shown in FIGS. 10A to 10E. However, the diffusion layer 40 is formed in the substrate surface of the inter-trench region RI. For this purpose, the impurity of the N⁺ type needs to be implanted in the whole region before the trenches 50 are formed in the substrate 1. After the N⁺ type diffusion layer 40 is formed, the plurality of trenches 50 are formed to extend in the Y direction. As a result, the N⁺ type diffusion layer 40 is formed in the substrate surface of the inter-trench region RI.

According to the nonvolatile semiconductor memory device according to the second embodiment, the effect similar to the first embodiment is achieved. That is, according to the second embodiment, the trench 50 is provided in the substrate 1, and the source/drain layers 40 are provided at a same level in the Z direction (the direction of the substrate depth). The source/drain layers 40 are not provided separately for the upper side and under side of the trench 50. Therefore, the total gate length L (=Lcg+Lwg+Lcg2) can be secured for the 2 directions of the horizontal direction (X direction) and the vertical direction (Z direction o). In other words, the total gate length L can be secured along not a straight line but a polygonal line. Therefore, even if the fine processing technique is developed to make the parameter F small, the total gate length L can be secured enough by adjusting the depth of the trench 50. As a result, when the miniaturization is accomplished in size, it can be avoided that the device cannot be realized due to the dissatisfaction of the total gate length L. That is, the size of the memory cell can be determined in accordance with the development of the fine processing technique. Furthermore, according to the second embodiment, a side portion of the source/drain layer 40 is surrounded by the sidewall of the trench 50. A depletion layer only extends below (the direction of the substrate depth), and does not extend horizontally. Therefore, even if the high voltage is applied to the source/drain layer 40, the punch-through is prevented from being caused between those sources and drains. That is, an additional effect that the reliability of the device is improved more is achieved compared with the first embodiment.

What is claimed is:

1. A nonvolatile semiconductor memory device comprising:
a semiconductor substrate having trenches formed to extend in parallel;
a first electrode formed on said semiconductor substrate through an insulating film in each of said trenches;
a second electrode formed on said first electrodes and said semiconductor substrate through said insulating film;
a diffusion layer formed in a predetermined depth of said semiconductor substrate in association with each of said trenches; and
a trap film as a part of said insulating film configured to trap electric charge,
wherein a channel region i,s formed between adjacent two of said diffusion layers without any diffusion layer.

2. The nonvolatile semiconductor memory device according to claim 1, wherein said diffusion layer is formed in each of inter trench portions of said semiconductor substrate.

3. The nonvolatile semiconductor memory device according to claim 2, wherein said trap film is formed between said second electrode and said semiconductor substrate in said trench.

4. The nonvolatile semiconductor memory device according to claim 1, wherein said diffusion layer is formed in each of portions of said semiconductor substrate under said trenches.

5. The nonvolatile semiconductor memory device according to claim 4, wherein said trap film is formed between said first electrode and the sidewall of said trench at least.

6. The nonvolatile semiconductor memory device according to claim 1, wherein a portion of said insulating film other than said trap film is different from said trap film in composition.

7. The nonvolatile semiconductor memory device according to claim 1, wherein said first electrode is formed to fill a whole of said trench, and
said second electrode is formed on said semiconductor substrate through said insulating film.

8. The nonvolatile semiconductor memory device according to claim 1, wherein said trenches are formed to extend in a first direction,
said diffusion layer is formed to extend in the first direction,
said first electrode is formed to extend in the first direction, and
said second electrode is formed to extend in a second direction orthogonal to the first direction.

9. The nonvolatile semiconductor memory device according to claim 1, wherein said trap film comprises;
a laminate film of an oxide film and a nitride film.

10. The nonvolatile semiconductor memory device according to claim 1, wherein said trap film is an insulating film in which a metal dot is formed.

11. A nonvolatile semiconductor memory device comprising:
a semiconductor substrate having trenches;
a source and a drain formed in said semiconductor substrate on both sides of a first trench of said trenches to sandwich said first trench;
a word gate provided on said semiconductor substrate through an insulating film in a bottom of said first trench;
a control gate formed on said semiconductor substrate through said insulating film to fill a remaining portion of said first trench; and
a trap film formed between said control gate and said semiconductor substrate in said first trench as a part of said insulating film to trap electric charge.

12. The nonvolatile semiconductor memory device according to claim 11, wherein a channel region between said source and said drain is formed along said first trench.

13. The nonvolatile semiconductor memory device according to claim 11, wherein said source is connected with a first bit line extending in a first direction,
said drain is connected with a second bit line extending in the first direction,
said word gate is connected with a first word line extending in the first direction, and
said control gate is connected with a second word line extending in a second direction orthogonal to the first direction.

14. A nonvolatile semiconductor memory device comprising:
a semiconductor substrate having first and second trenches which are adjacent to each other;
a source formed in said semiconductor substrate in said first trench;
a drain formed in said semiconductor substrate in said second trench;
a first control gate formed on said semiconductor substrate through an insulating film in a bottom of said first trench;
a second control gate formed on said semiconductor substrate through said insulating film in a bottom of said second trench;
a word gate formed said semiconductor substrate and said first and second control gates; and
a trap film formed between said first control gate and said semiconductor substrate in said first trench arid between said second control gate and said semiconductor substrate in said second trench as a part of said insulating film to trap electric charge.

15. The nonvolatile semiconductor memory device according to claim 14, wherein a channel region between said source and said drain is formed along an inter-trench portion of said semiconductor substrate.

16. The nonvolatile semiconductor memory device according to claim 14, wherein said source is connected with a first bit line extending in a first direction,
said drain is connected with a second bit line extending in the first direction,
said first control gate is connected with a first word line extending in the first direction,
said second control gate is connected with a second word line extending in the first direction, and
said word gate is connected with a third word line extending in a second direction orthogonal to the first direction.

17. The nonvolatile semiconductor memory device according to claim 14, wherein a portion of said insulating film other than said trap film is different from said trap film.

18. The nonvolatile semiconductor memory device according to claim 14, wherein said trap film comprises:
a laminate film of an oxide film and a nitride film.

19. The nonvolatile semiconductor memory device according to claim 1, wherein said trap film is formed as the part of said insulating film in which a metal dot is formed.
